(19) United States
(12) Patent Application Publication
(10) Pub. No.: US 2013/0148270 A1
(43) Pub. Date: Jun. 13, 2013

(54) ELECTRONIC DEVICE CASE WITH REMOVABLE ATTACHMENTS

(71) Applicants: Robb Fujioka, Manhattan Beach, CA (US); Daniel Miyahara, Manhattan Beach, CA (US)

(72) Inventors: Robb Fujioka, Manhattan Beach, CA (US); Daniel Miyahara, Manhattan Beach, CA (US)

(21) Appl. No.: 13/323,719

(22) Filed: Dec. 12, 2011

(51) Int. Cl. H05K 5/00

(52) U.S. Cl. 361/679.01

(57) ABSTRACT

The invention is a portable electronic device, or case for a portable electronic device, which has attachment structures that allow appendages and other accessories to be removably connected and disconnected to the case for amusement and entertainment purposes.

### FIELD OF THE INVENTION

The invention relates to a device, method, and system for removably attaching appendages and other accessories to an electronic device. More particularly, the invention is a case that fits around an electronic device. The electronic device case has attachment structures that allow toys, appendages, and other accessories to be connected and disconnected to the case for amusement and entertainment purposes.

### BACKGROUND OF THE INVENTION

For the past several decades, computers have been a source of amusement and entertainment for children and adults alike. Specifically, computers run software programs, including drawing programs, game programs, and educational programs that provide users hours of enjoyment. The computer itself, however, was merely the platform for the entertaining software programs. Recent advances in computer and electronics technology have allowed computers to become both portable and more powerful at the same time. The portability of computers has allowed users to bring their computers, and integrated entertainment software, to where ever they travel. Indeed, this portability has led to the creation of a specific type of computer called portable electronic gaming devices. In addition to portable electronic gaming devices, portable electronic readers and handheld personal digital assistants have become popular business and entertainment devices.

More recently, tablet computers have become popular as a way for children and adults to combine the business, reading, gaming, and other entertainment functions onto a single portable, but very powerful, platform. Importantly, with the popularity of tablet computers, and the touch screen functionality they typically possess, external control devices, such as joysticks, directional pads, keyboards, knobs, mouse devices, e-writing styluses, and thumb control pads have become less of a part of the portable electronic devices. Although the internalization of control components makes for a sleek, adult friendly computer, the lack of external components is not always desirable if the computer is being used by a child.

There are many types of portable electronic devices, including tablet computers, which are specifically designed to be used by children. For example, U.S. Published Patent Application No. 2009/0113091, filed by Miller, discloses a portable electronic device that has child friendly functionally dedicated external control devices. The Miller application discloses a digital arts and crafts computer peripheral toy device that plugs into a computer and allows a child to create digital works of art. The front of the device has graphical and raised buttons on the sides of the display monitor. The graphics displayed on the raided buttons match the functionality for each particular and unique button. Although the dedicated and functional buttons of the Miller application provide some stimulation for the child using the device, these buttons are not purely ornamental and if played with at the wrong time, might result in the computer performing unwanted tasks. Further, the graphic buttons of Miller are not removable or replaceable.

Although the Miller application and other child friendly portable electronic devices available in the market come in many shapes, sizes, and colors, and have many different types of functional control components that are engageable by the young user, no portable electronic device is available that has removable accessories that convert the computer into a personalized toy.

In addition to portable electronic devices having multi-functional external control components, some portable electronic devices also have dedicated external control components. Thus, what is needed is a portable electronic device or case for a portable electronic device that has attachment structures that allow toys, appendages, and other accessories to be removably connected and disconnected to the case for amusement and entertainment purposes.

### SUMMARY OF THE INVENTION

To minimize the limitations in the prior art, and to minimize other limitations that will become apparent upon reading and understanding the present specification, the present invention discloses a new and useful case for a portable electronic device that has attachment structures that allow toys, appendages, and other accessories to be connected and disconnected to the case for amusement and entertainment purposes.

One embodiment of the invention is a portable electronic device case comprising: a case; one or more accessories. The case is adapted to fit onto an electronic device. The case has a plurality of sides, a back plate, and one or more accessory connectors. The accessories and the accessory connectors are adapted to removably interconnect. Preferably, the accessories may be children's toys, animal appendages, handles, or stands. If the accessories are toys or appendages, the electronic device with case is transformed into a toy or a toy animal. The accessories are preferably poseable. The accessory connectors are preferably on a back plate, but may be on the sides of the case. The case may have one or more apertures, wherein the apertures are aligned with one or more ports of the electronic device, such that the one or more ports are accessible.

Another embodiment of the invention is an electronic device comprising: a housing; one or more electronic components; and one or more accessories. The housing contains the electronic components of the electronic device and has a plurality of sides, a back plate, and one or more accessory connectors. The accessories and the accessory connectors are adapted to removably interconnect. Preferably, the accessories may be children's toys, animal appendages, handles, or stands. If the accessories are toys or appendages, the electronic device with case is transformed into a toy or a toy animal. The accessories are preferably poseable. The accessory connectors are preferably on the back plate of the housing, but may be on the sides of the housing. The electronic device may further comprise: a case; wherein the case has one or more openings wherein said one or more openings are aligned with the one or more accessory connectors, such that the one or more accessory connectors are accessible.

It is an object of the present invention to overcome the limitations of the prior art. It is a further object of the present invention to provide the user with a tablet computer case that has the ability to connect with one or more accessories, such as a handle, toy, or stand.

It is an object of the present invention to provide easy to use and entertaining computer case.

These, as well as other components, steps, features, objects, benefits, and advantages, will now become clear from a review of the following detailed description of illustrative embodiments, the accompanying drawings, and the claims.

### BRIEF DESCRIPTION OF THE DRAWINGS

The drawings are of illustrative embodiments. They do not illustrate all embodiments. Other embodiments may be used in addition or instead. Details which may be apparent or unnecessary may be omitted to save space or for more effective illustration. Some embodiments may be practiced with additional components or steps and/or without all of the components or steps which are illustrated. When the same numeral appears in different drawings, it refers to the same or like components or steps.

FIG. 1 is an illustration of a front view of one embodiment of the electronic device case.

FIG. 2 is an illustration of a perspective back view of one embodiment of the electronic device case and shows one embodiment of the accessory connectors.

FIG. 3 is an illustration of a front view of one embodiment of an accessory.

FIG. 4 is an illustration of a front view of one embodiment of the electronic device case with accessories attached.

FIG. 5 is an illustration of a front view of another embodiment of the electronic device case with accessories attached.

FIG. 6 is an illustration of a side view of one embodiment of the electronic device case showing one embodiment of the accessory connectors.

FIG. 7 is an illustration of a perspective view of one embodiment of the electronic device case showing one embodiment of the accessory connectors.

FIG. 8 is an illustration of a front view of one embodiment of the electronic device case showing that the accessory is a handle.

FIG. 9 is an illustration of a side view of one embodiment of the electronic device case showing that the accessory is a stand.

FIG. 10 is an illustration of a front view of one embodiment of the electronic device.

FIG. 11 is an illustration of a perspective back view of one embodiment of the electronic device showing the accessory connectors.

FIG. 12 is an illustration of a perspective back view of one embodiment of the electronic device showing a case with openings for the accessory connectors.

### DETAILED DESCRIPTION OF THE DRAWINGS

In the following detailed description of various embodiments of the invention, numerous specific details are set forth in order to provide a thorough understanding of various aspects of one or more embodiments of the invention. However, one or more embodiments of the invention may be practiced without some or all of these specific details. In other instances, well-known methods, procedures, and/or components have not been described in detail so as not to unnecessarily obscure aspects of embodiments of the invention.

While multiple embodiments are disclosed, still other embodiments of the present invention will become apparent to those skilled in the art from the following detailed description, which shows and describes illustrative embodiments of the invention. As will be realized, the invention is capable of modifications in various obvious aspects, all without departing from the spirit and scope of the present invention. Accordingly, the screen shot figures, and the detailed descriptions thereof, are to be regarded as illustrative in nature and not restrictive. Also, the reference or non-reference to a particular embodiment of the invention shall not be interpreted to limit the scope of the invention.

In the following description, certain terminology is used to describe certain features of one or more embodiments of the invention. For instance, “computer” or “electronic device” refers to any electronic data processing unit or device that processes information with an integrated circuit chip, including without limitation, mainframe computers, work stations, servers, desktop computers, portable computers, laptop computers, smart phone, embedded computers, wireless devices including cellular phones, personal digital assistants, portable game players, portable gaming devices, portable electronic gaming devices, electronic devices, portable electronic devices, tablet computers, and hand-held computers.

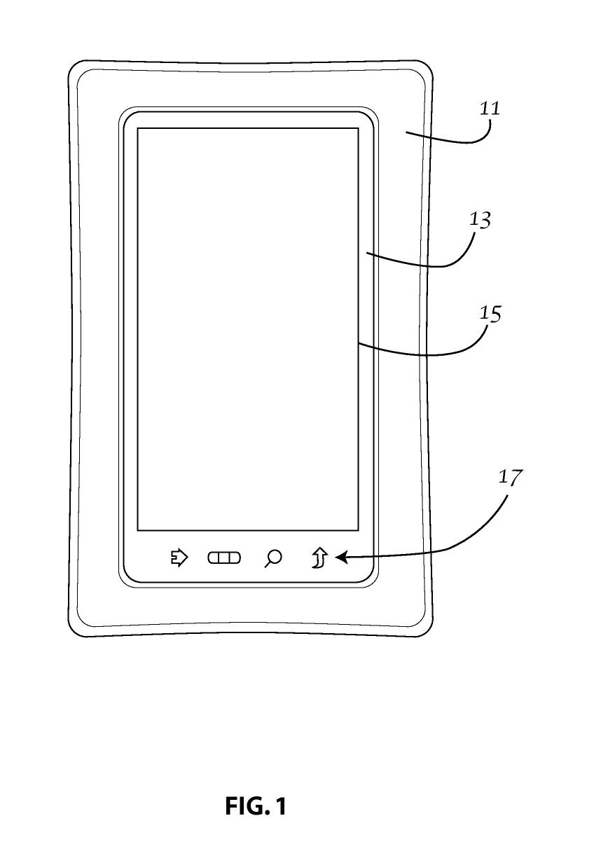

FIG. 1 is an illustration of a front view of one embodiment of the electronic device case. FIG. 1 shows that the electronic device case 11, also referred to as a case, is preferably a cover for electronic device 13. As shown in FIG. 1, the case has a large front opening that allows the viewer to view display screen 15 and access the controls 17 of the electronic device 13. Although electronic device 13 is shown as a tablet computer, which is preferred, it should be understood that electronic device 13 may be any type of computer, electronic device, or smart phone. Preferably, the case 11, which may also be referred to as a skin or covering, is made from high impact plastic or rubber, but the case 11 may be made out of any natural, synthetic, or man-made material without deviating from the scope of the invention. As shown in FIG. 1, the case 11 is preferably a slip on case that holds itself snuggly around the electronic device 13. Although the case 11 is shown as a single unitary piece, it should be understood that the case 11 may be made from any number of parts and may cover or attach to the electronic device in various other ways.

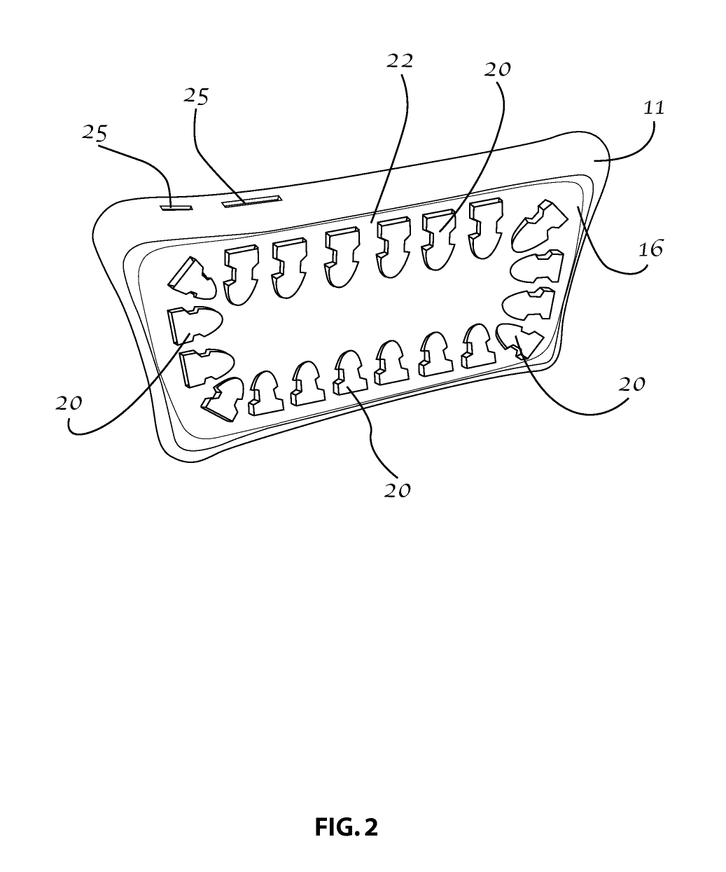

FIG. 2 is an illustration of a perspective back view of one embodiment of the electronic device case and shows one embodiment of the accessory connectors. As shown in FIG. 2, the back plate 16 of the case 11 preferably has one or more accessory connectors 20. Although the accessory connectors 20, as shown in FIG. 2, are preferably slots that engage with a corresponding slot member of an accessory, the accessory connectors 20 may be any shape so long as they removably engage with the accessories. FIG. 2 also shows that the case 11 preferably has apertures or holes 25 that allow the user to access the ports of the electronic device.

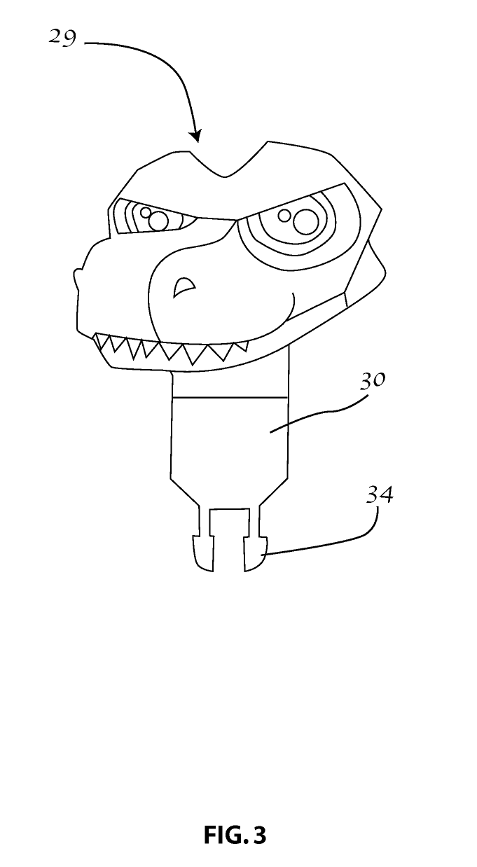

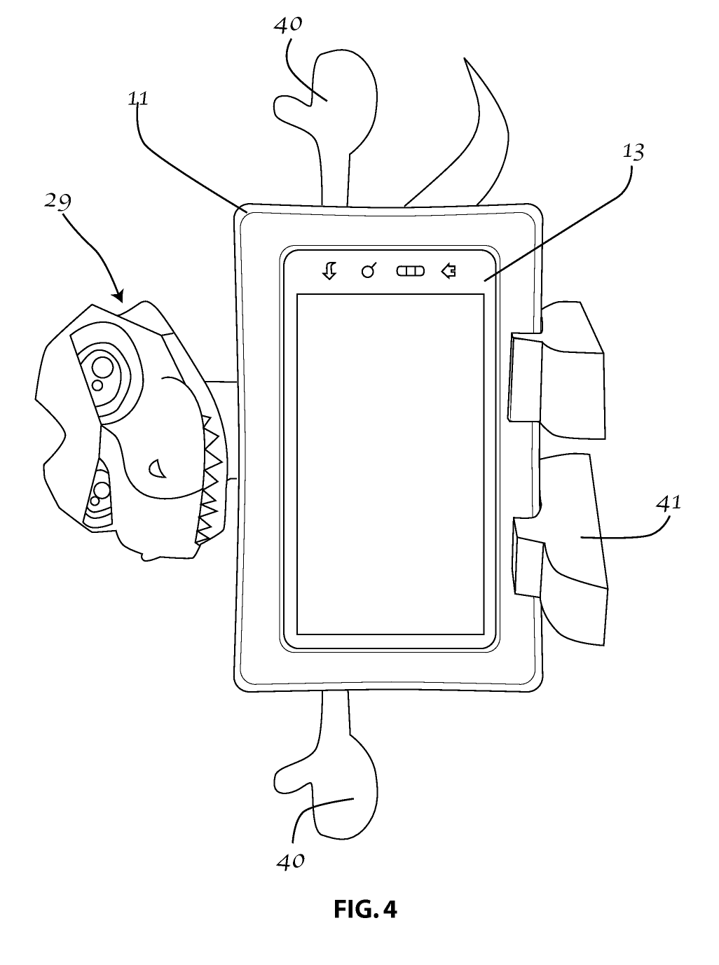

FIG. 3 is an illustration of a front view of one embodiment of an accessory. As shown in FIG. 3, the accessory 29 is preferably a children's toy, such as a monster, animal, or appendage of a toy (head, arm, or leg). FIG. 3 shows how the accessory 29 has a connection end 30 which removably interconnects with accessory connector 20 (shown in FIG. 2). Snap 34 is preferably designed to interconnect with accessory connector 20 (shown in FIG. 2), such that accessory 29 is held in place until the user wants to disconnect and remove the accessory 29.

FIG. 4 is an illustration of a front view of one embodiment of the electronic device case with accessories attached. As shown in FIG. 4, the accessories 29, 40, and 41 may be connected to the accessory connectors such that the electronic device 13 is transformed into a toy. Although a monster is shown in FIG. 4, it should be understood that the accessories may be any shape, pattern, color, or size. Preferably, the accessories 29, 40, and 41 are poseable such that the arm accessories 40 may be placed and held in different positions. Typically, the accessories are made from plastic, rubber, and/or metal. The poseable accessories are typically made from rubber covering bendable metal wire.

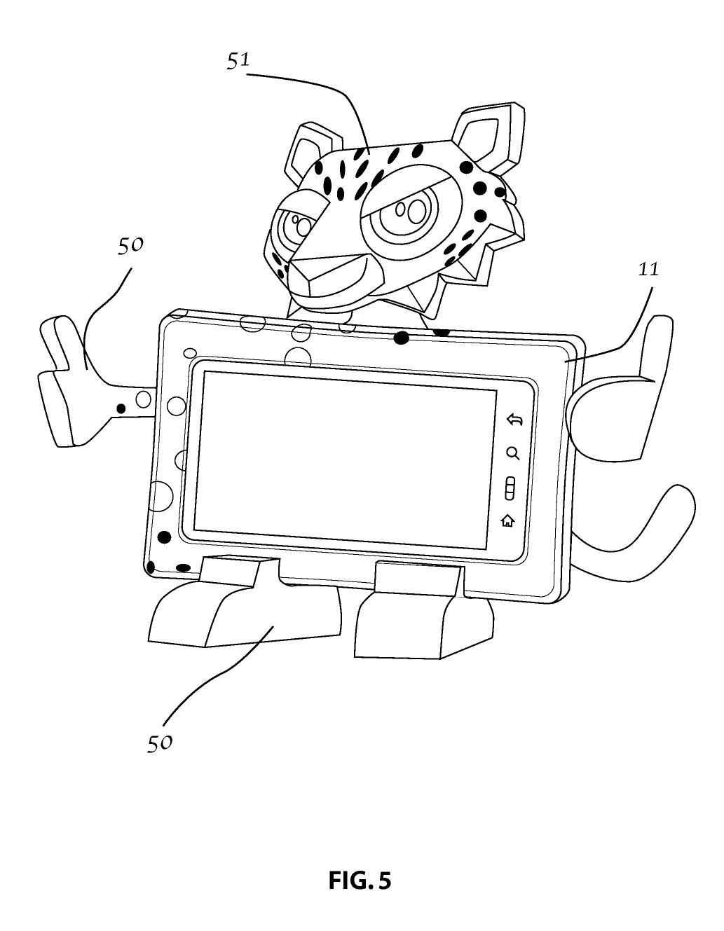

FIG. 5 is an illustration of a front view of another embodiment of the electronic device case with accessories attached. FIG. 5 shows that the accessories 50 and 51 may be animal appendages, which, when connected to the case 11, transform the electronic device into a toy animal. FIG. 5 also shows how accessory 50 is poseable. Specifically, accessory 50 is bent and posed toward the user of the electronic device case 11.

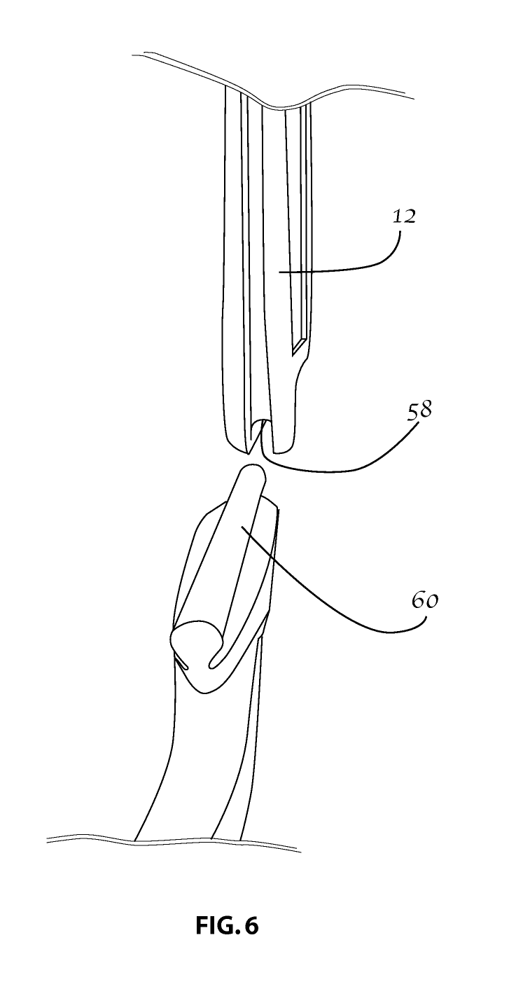

FIG. 6 is an illustration of a side view of one embodiment of the electronic device case showing one embodiment of the accessory connectors. FIG. 6 shows how the accessory connector 58 may be on the side of case 12. In this embodiment, the accessory 60 slideably interconnects with accessory connector 58.

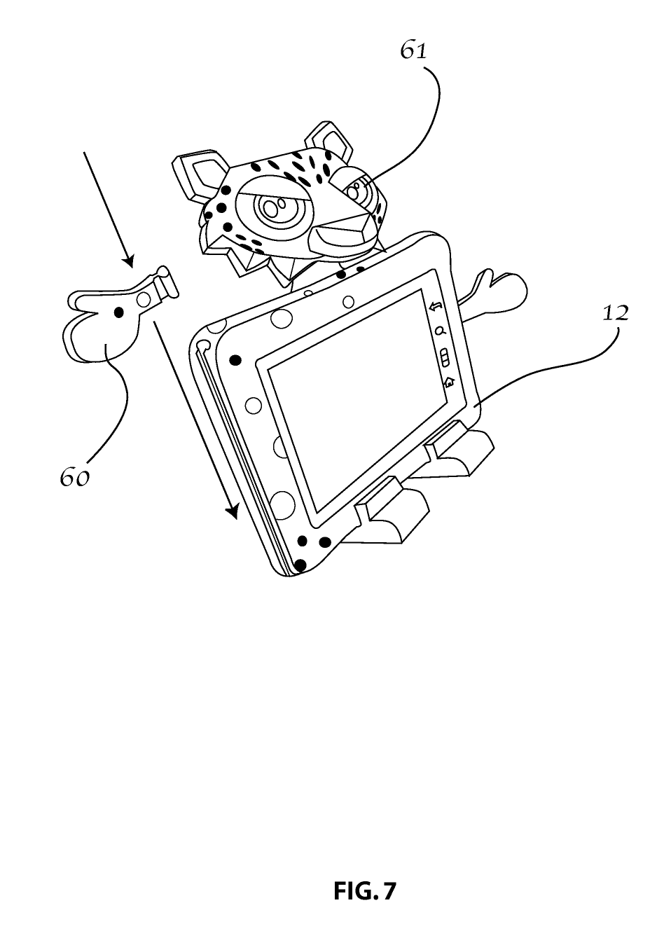

FIG. 7 is an illustration of a perspective view of one embodiment of the electronic device case showing one embodiment of the accessory connectors. FIG. 7 shows how the accessory connector 58 slideably connects with accessory 60. As shown in FIG. 7, accessory 61 has already been slid into place.

Although only two types of accessory connectors are shown in the drawings, it should be understood that any connection device might be used, including, but not limited to: friction, snap, hook and loop, button, slot and tab, insertable, slidable, and/or magnetic.

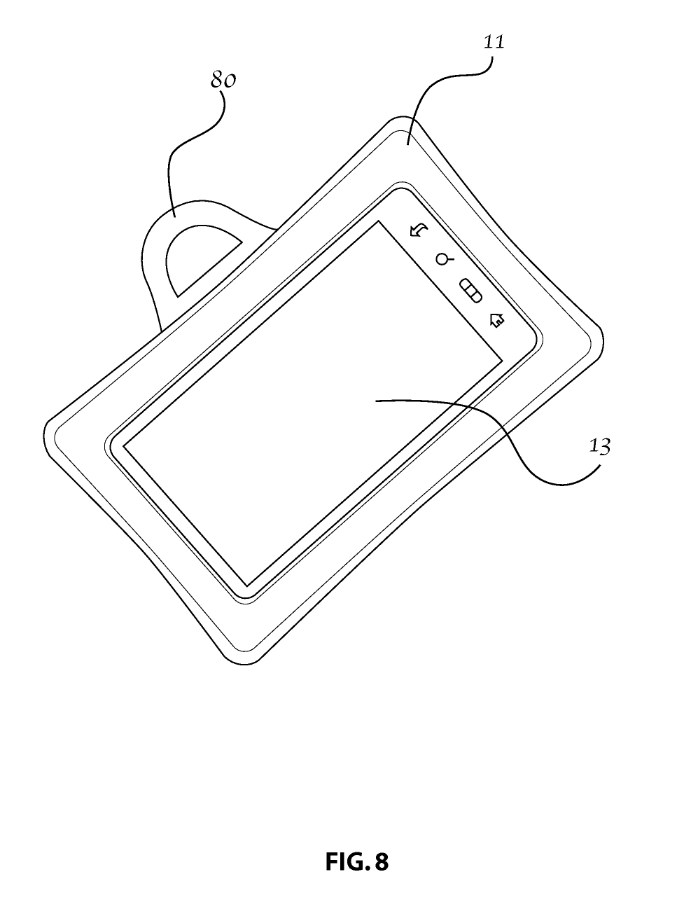

FIG. 8 is an illustration of a front view of one embodiment of the electronic device case showing that the accessory is a handle. As shown in FIG. 8, the accessory may be a handle 80, which allows the user to carry the electronic device 13 and pretend that the electronic device 13 is a briefcase.

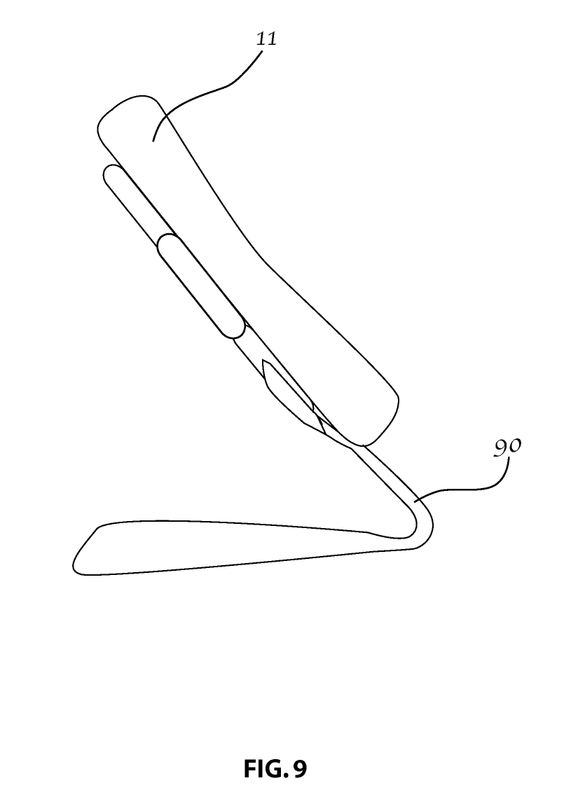

FIG. 9 is an illustration of a side view of one embodiment of the electronic device case showing that the accessory is a stand. As shown in FIG. 9, the accessory may be a stand 90, which allows the user to set up the case 11 and electronic device 13 in a stationary position.

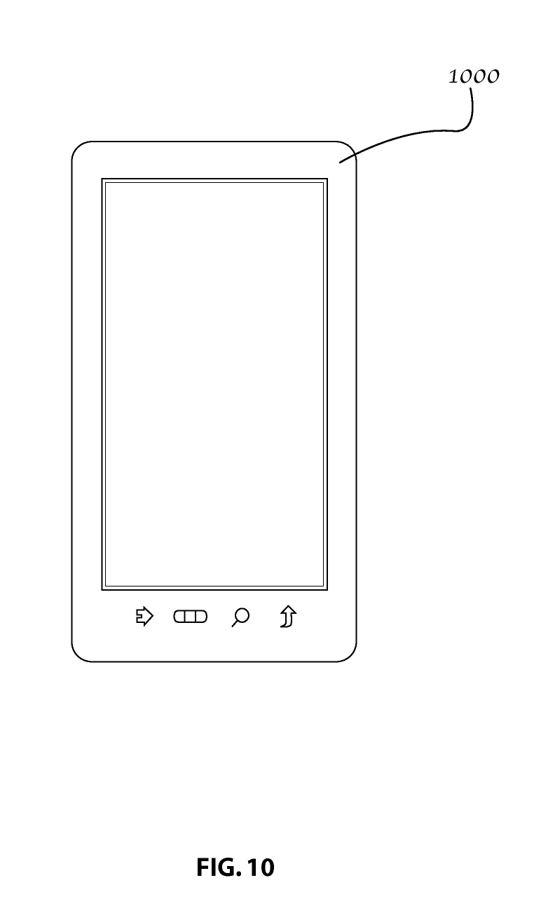

FIG. 10 is an illustration of a front view of one embodiment of the electronic device. As shown in FIG. 10, another embodiment of the invention is an electronic device 1000 that does not have a case with accessory connectors.

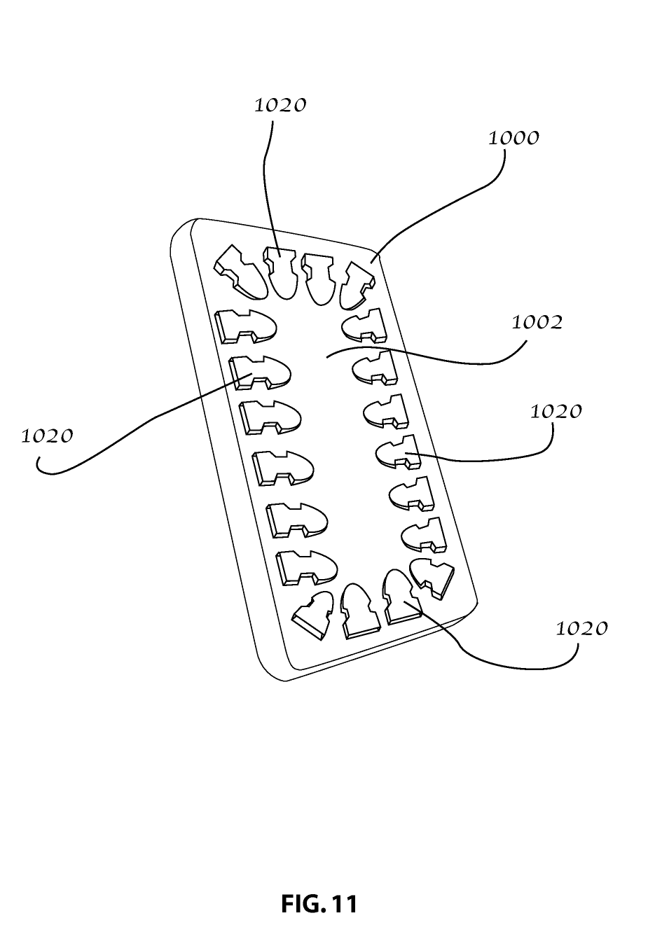

FIG. 11 is an illustration of a perspective back view of one embodiment of the electronic device showing the accessory connectors. FIG. 11 shows that the accessory connectors 1020 are directly attached to, or part of, the housing 1002 of the electronic device 1000. With this embodiment, the accessories are directly connected to the housing of the electronic device 1000 and not a case that covers the electronic device 1000. Although only one type of accessory connector 1020 is shown, it should be understood that any connection device may be used, including, but not limited to: friction, snap, hook and loop, button, insertable, slidable, and/or magnetic.

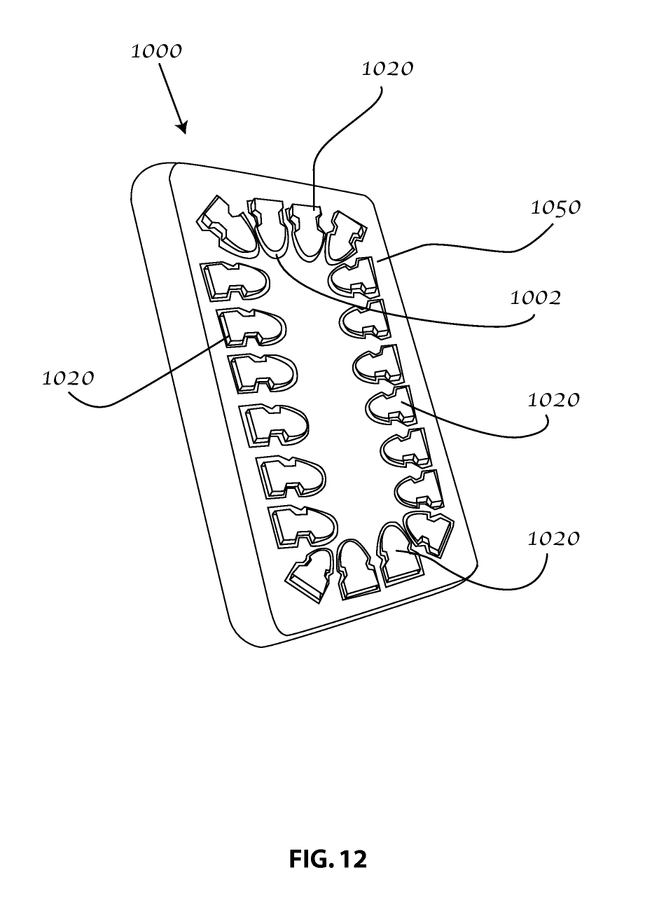

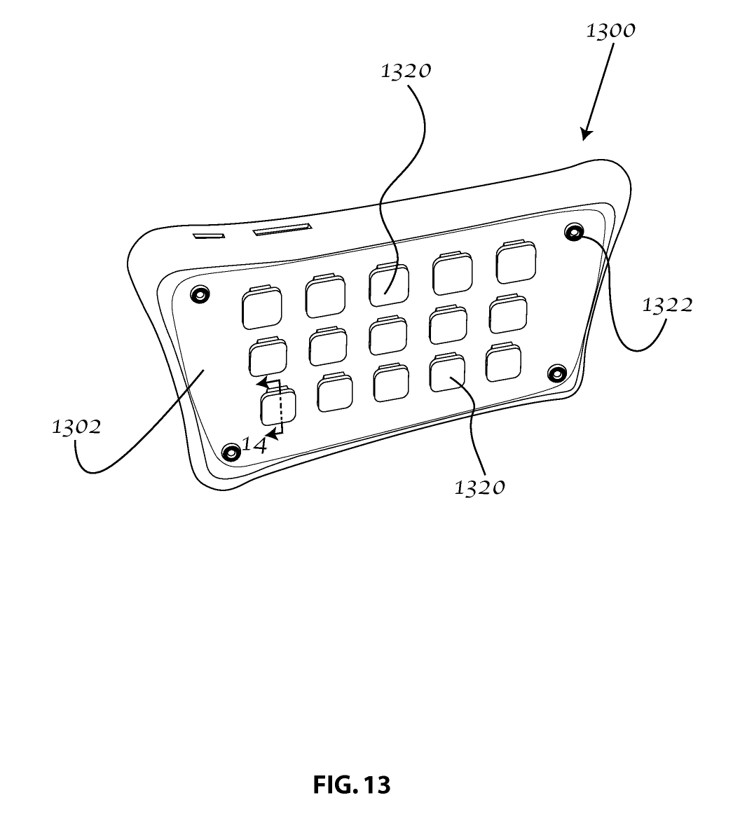

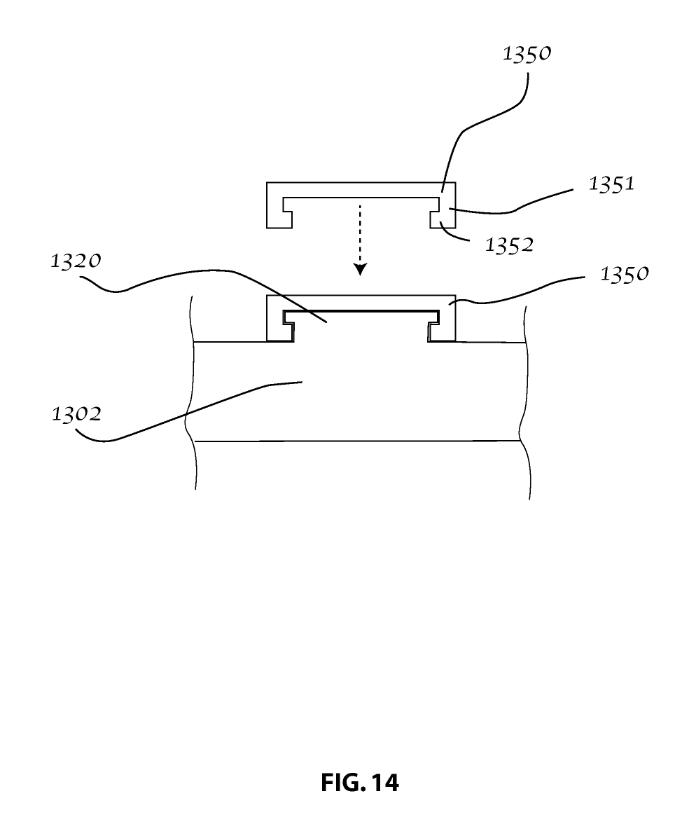

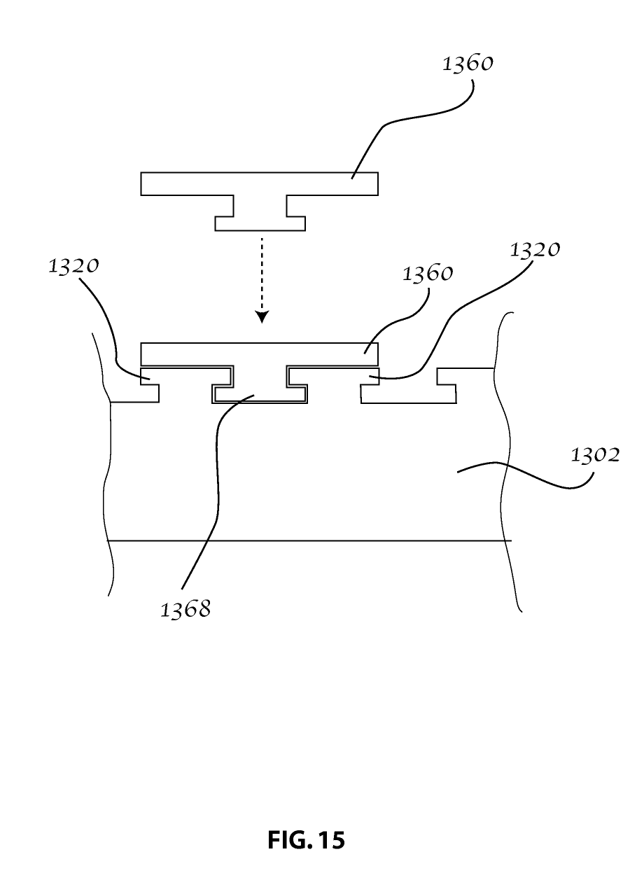

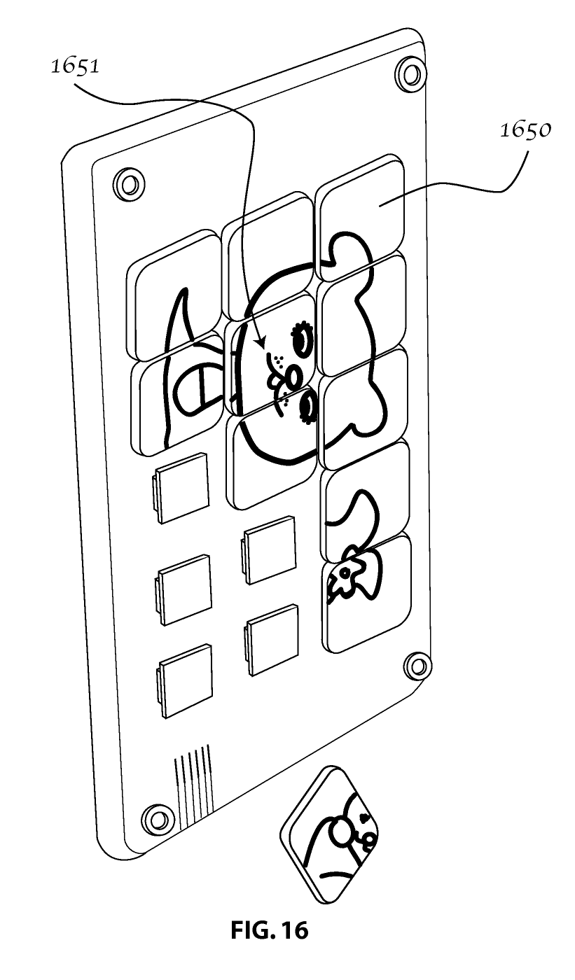

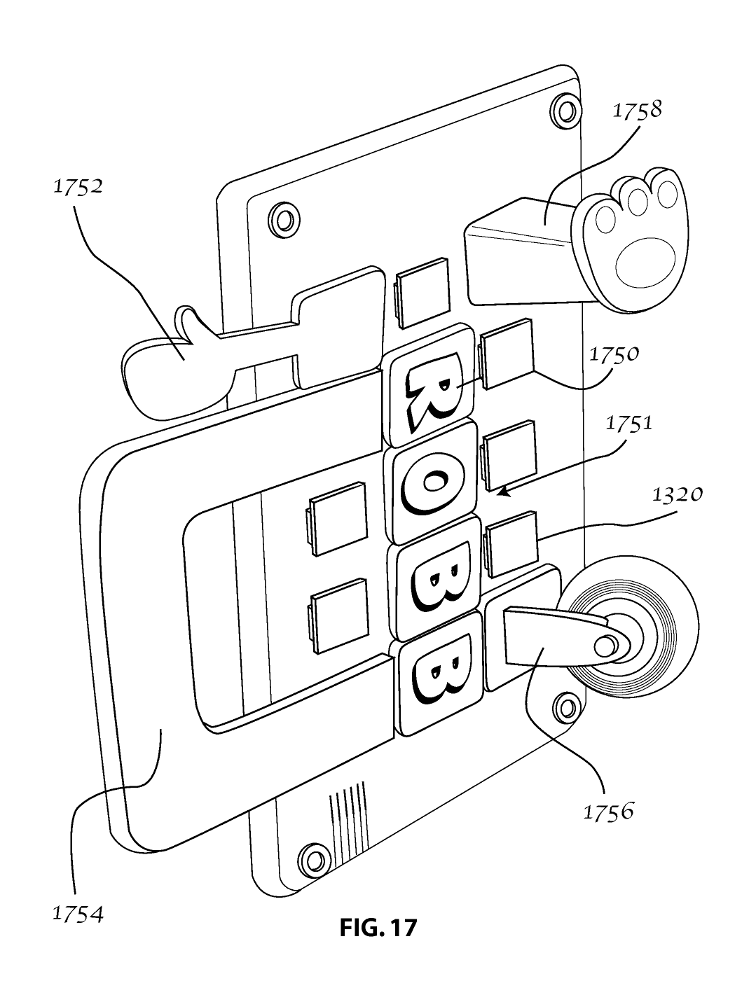

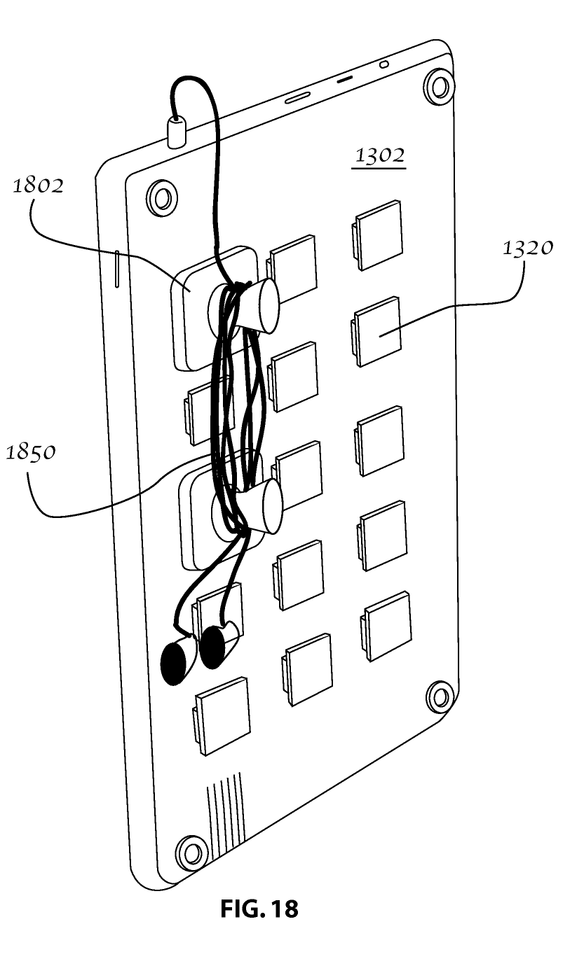

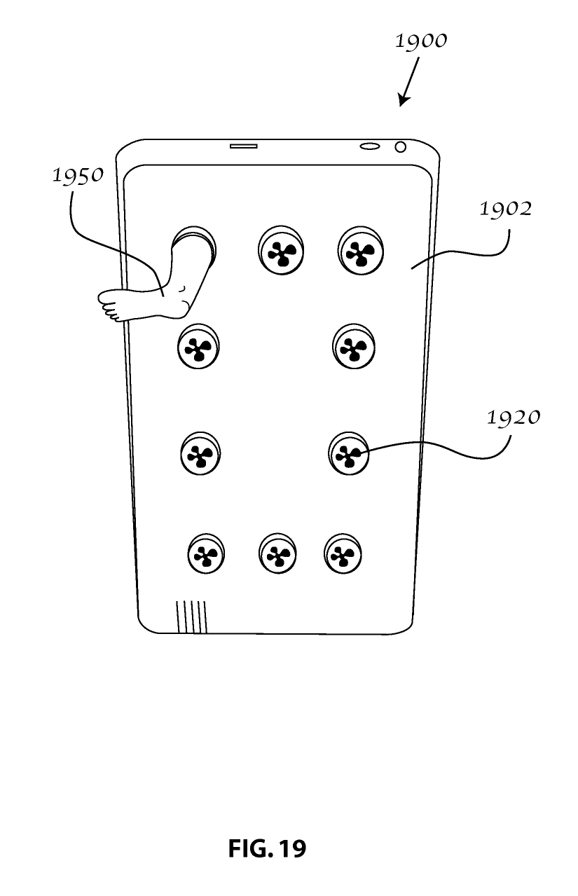

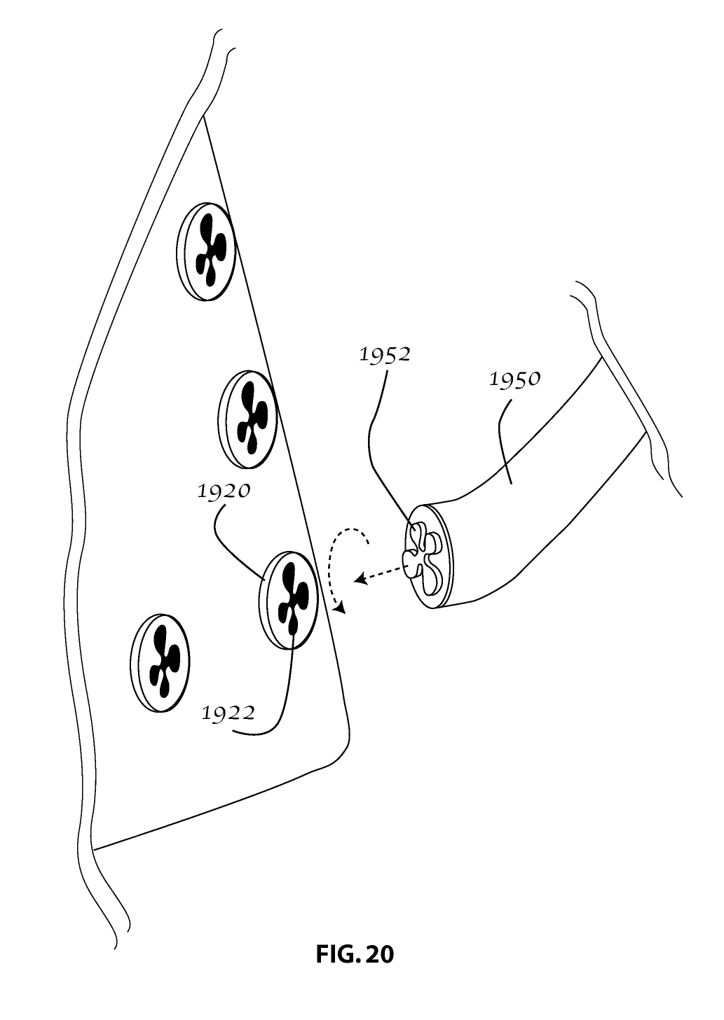

FIG. 12 is an illustration of a perspective back view of one embodiment of the electronic device showing a case with openings for the accessory connectors. As shown in FIG. 12, the electronic device 1000 has a housing 1002 with accessory connectors 1020 that are part of, or directly connected to, the housing 1002. FIG. 12 shows how case 1050 is placed over electronic device 1000 such that the accessory connectors 1020 are accessible through openings in case 1050.

Unless otherwise stated, all measurements, values, ratings, positions, magnitudes, sizes, locations, and other specifications which are set forth in this specification, including in the claims which follow, are approximate, not exact. They are intended to have a reasonable range which is consistent with the functions to which they relate and with what is customary in the art to which they pertain.

The foregoing description of the preferred embodiment of the invention has been presented for the purposes of illustration and description. While multiple embodiments are disclosed, still other embodiments of the present invention will become apparent to those skilled in the art from the above detailed description, which shows and describes illustrative embodiments of the invention. As will be realized, the invention is capable of modifications in various obvious aspects, all without departing from the spirit and scope of the present invention. Accordingly, the detailed description is to be regarded as illustrative in nature and not restrictive. Also, although not explicitly recited, one or more embodiments of the invention may be practiced in combination or conjunction with one another. Furthermore, the reference or non-reference to a particular embodiment of the invention shall not be interpreted to limit the scope the invention. It is intended that the scope of the invention not be limited by this detailed description, but by the claims and the equivalents to the claims that are appended hereto.

Except as stated immediately above, nothing which has been stated or illustrated is intended or should be interpreted to cause a dedication of any component, step, feature, object, benefit, advantage, or equivalent to the public, regardless of whether it is or is not recited in the claims.

What is claimed is:

1. A portable electronic device case comprising:
a case;
one or more accessories;
wherein said case is adapted to fit onto an electronic device;
wherein said case has a plurality of sides, a back plate, and one or more accessory connectors;
wherein said one or more accessories and said one or more accessory connectors are adapted to removably interconnect.

2. The portable electronic device case of claim 1, wherein said one or more accessories are one or more children's toys, such that when said one or more accessories are connected to said case, said case is transformed into a toy.

3. The portable electronic device case of claim 1, wherein said one or more accessories are one or more animal appendages, such that when said one or more accessories are connected to said case, said case is transformed into a toy animal.

4. The portable electronic device case of claim 1, wherein said one or more accessories are poseable.

5. The portable electronic device case of claim 1, wherein said one or more accessories are one or more electronic device stands.

6. The portable electronic device case of claim 1, wherein said one or more accessories are one or more handles.

7. The portable electronic device case of claim 1, wherein said one or more accessory connectors are on said back plate of said case.

8. The portable electronic device case of claim 1, wherein said one or more accessory connectors are on said plurality of sides of said case.

9. The portable electronic device case of claim 1, wherein said case is further comprised of one or more apertures,
wherein said one or more apertures are aligned with one or more ports of said electronic device, such that said one or more ports are accessible.

10. A portable electronic device case comprising:
a case;
one or more accessories;
wherein said case is adapted to fit onto an electronic device;
wherein said case has a plurality of sides, a back plate, and one or more accessory connectors;
wherein said one or more accessories and said one or more accessory connectors are adapted to removably interconnect;
wherein said one or more accessories are selected from the group consisting of: one or more children's toys, one or more poseable animal appendages, one or more handles, and one or more electronic device stands;
wherein said one or more accessory connectors are on said back plate of said case;
wherein said case is further comprised of one or more apertures,
wherein said one or more apertures are aligned with one or more ports of said electronic device, such that said one or more ports are accessible.

11. An electronic device comprising:
a housing;
one or more electronic components;
one or more accessories;
wherein said housing contains said one or more electronic components of said electronic device;
wherein said housing has a plurality of sides, a back plate, and one or more accessory connectors;
wherein said one or more accessories and said one or more accessory connectors are adapted to removably interconnect.

12. The electronic device of claim 11, wherein said one or more accessories are children's toys, such that when said one or more accessories are connected to said one or more accessory connectors, said electronic device is transformed into a toy.

13. The electronic device of claim 11, wherein said one or more accessories are animal appendages, such that when said one or more accessories are connected to said one or more accessory connectors, said electronic device is transformed into a toy animal.

14. The electronic device of claim 11, wherein said one or more accessories are poseable.

15. The electronic device of claim 11, wherein said one or more accessories are one or more electronic device stands.

16. The electronic device of claim 11, wherein said one or more accessories are one or more handles.

17. The electronic device of claim 11, wherein said one or more accessory connectors are on said back plate of said housing.

18. The electronic device of claim 11, wherein said one or more accessory connectors are on said plurality of sides of said housing.

19. The electronic device of claim 11, further comprising:
a case;
wherein said case has one or more openings wherein said one or more openings are aligned with said one or more accessory connectors, such that said one or more accessory connectors are accessible.

20. The portable electronic device case of claim 1, wherein said one or more accessories are one or more wheels.

21. The portable electronic device case of claim 11, wherein said one or more accessories are one or more wheels.
